(19) United States
(12) Patent Application Publication
(10) Pub. No.: US 2017/0294527 A1
(43) Pub. Date: Oct. 12, 2017

(54) SEMICONDUCTOR DEVICE AND METHOD FOR MANUFACTURING THE SAME

(71) Applicant: Mitsubishi Electric Corporation, Tokyo (JP)

(72) Inventors: Kenji SUZUKI, Tokyo (JP); Tetsuo TAKAHASHI, Tokyo (JP); Mitsuru KANEDA, Tokyo (JP); Ryu KAMIBABA, Tokyo (JP)

(73) Assignee: Mitsubishi Electric Corporation, Tokyo (JP)

(21) Appl. No.: 15/377,521

(22) Filed: Dec. 13, 2016

(30) Foreign Application Priority Data
Apr. 6, 2016 (JP) 2016-076271

(51) Int. Cl. H01L 29/739; H01L 29/66; H01L 29/423; H01L 21/265; H01L 21/324; H01L 29/36; H01L 29/10

(52) U.S. Cl. CPC H01L 29/7397; H01L 29/36; H01L 29/66348; H01L 29/1095; H01L 21/265; H01L 21/324; H01L 29/4236

(57) ABSTRACT

An insulated gate bipolar transistor (IGBT) includes: a p base layer disposed close to a front surface of an n-type silicon substrate; and a deep n⁺ buffer layer and a shallow n⁺ buffer layer disposed close to a back surface of the n-type silicon substrate. The p base layer has a higher impurity concentration than the n-type silicon substrate. The deep n⁺ buffer layer and shallow n⁺ buffer layer have higher impurity concentrations than the n-type silicon substrate. The deep n⁺ buffer layer is disposed throughout a region close to the back surface in the n-type silicon substrate. The shallow n⁺ buffer layer is selectively disposed close to the back surface in the n-type silicon substrate. The shallow n⁺ buffer layer has a higher impurity concentration than the deep n⁺ buffer layer, and is shallower from the back surface than the deep n⁺ buffer layer.

### BACKGROUND OF THE INVENTION

### Field of the Invention

The present invention relates to semiconductor devices such as insulated gate bipolar transistors (IGBTs).

### Description of the Background Art

In light of energy savings, IGBTs and diodes are used in power modules for variable-speed control of three-phase motors in fields, such as general-purpose inverters and AC servos. Reducing inverter losses requires less switching losses and lower turn-on voltages of the IGBTs and diodes.

Turn-on voltages of the IGBTs are mostly resistances of n-type thick base layers (drift layers) necessary for maintaining breakdown voltage of the IGBTs. Thin wafers (semiconductor substrates) on which the IGBTs are disposed are effective to reduce the resistances. However, the thin wafers cause depletion layers to reach back surfaces (surfaces close to collectors) of the wafers when voltages are applied to collector electrodes, thus resulting in a decrease in breakdown voltage or an increase in leakage current. Accordingly, a typical IGBT has a surface close to a collector, on which an n⁺ buffer layer having a higher impurity concentration than a substrate is disposed at a shallow depth (hereinafter, this buffer layer is referred to as a “shallow n⁺ buffer layer”).

Development in wafer processing technique has enabled wafers of the IGBTs to be so thin almost at their maximum that the IGBTs have desired breakdown voltage. For a thin wafer of an IGBT, a shallow n⁺ buffer layer can be disposed in a position close to a back surface of the wafer. Here, applying power voltage and surge voltage (=L×di/dt) between the collector and emitter of the IGBT after the IGBT operates as a switch causes a depletion layer to reach the position close to the back surface. If the depletion layer reaches the position close to the back surface, carriers are exhausted, thus unfortunately causing voltage and current to oscillate.

An exemplary technique for addressing such a problem is placing, in the position close to the back surface of the wafer, an n⁺ buffer layer that has an impurity concentration lower than an impurity concentration of the shallow n⁺ buffer layer, and is deeper from the back surface of the wafer (10 μm or more in depth) than the shallow n⁺ buffer layer (hereinafter, this buffer layer is referred to as a “deep n⁺ buffer layer”). Providing the deep n⁺ buffer layer would stop the spread of the depletion layer slowly if a high voltage is applied to a collector electrode while the IGBT performs switching. As a result, the carriers close to the back surface is prevented from their exhaustion and thus remain. This prevents a sudden increase in voltage.

However, in the technique, which uses the deep n⁺ buffer layer, the depletion layer needs to stop extending beyond the deep n⁺ buffer layer while the IGBT is turned off so that the carriers remain in the position close to the back surface. Thus, it is very difficult to optimize an impurity concentration of the deep n⁺ buffer layer. If the impurity concentration varies depending on changes in implantation amount of an impurity or on changes in condition of heating after ion implantation, voltage can greatly oscillate during the turn-off, or the depletion layer can reach the position close to the back surface in applying a high voltage to the collector electrode, to thus result in an increase in leakage current.

To solve these problems, proposed is a “two-stage buffer structure” that includes a shallow n⁺ buffer layer and a deep n⁺ buffer layer (e.g., Japanese Patent No. 3325752 and Japanese Patent Application Laid-Open No. 2013-138172).

A conventional IGBT with the two-stage buffer structure reduces leakage current and prevents voltage from oscillation while the IGBT is turned off. However, such an IGBT provides a small supply of holes from the back surface of a wafer of the IGBT. This unfortunately results in a reduction in breakdown capacity (short-circuit capacity) while the IGBT is short-circuited.

### SUMMARY OF THE INVENTION

It is an object of the present invention to provide a semiconductor device that is capable of reducing leakage current, preventing voltage from oscillation while the semiconductor device is turned off, and improving a short-circuit capacity.

A semiconductor device according to an embodiment of the present invention includes: a semiconductor substrate having a first main surface and a second main surface; a first semiconductor layer having n-type conductivity and disposed in the semiconductor substrate; a second semiconductor layer having p-type conductivity and disposed close to the first main surface in the first semiconductor layer; and a third semiconductor layer and a fourth semiconductor layer each having n-type conductivity and disposed close to the second main surface in the first semiconductor layer. The second semiconductor layer has a higher impurity concentration than the first semiconductor layer. The third semiconductor layer and the fourth semiconductor layer have higher impurity concentrations than the first semiconductor layer. The third semiconductor layer is disposed throughout a region close to the second main surface in the first semiconductor layer. The fourth semiconductor layer is selectively disposed close to the second main surface in the first semiconductor layer. The fourth semiconductor layer has a higher impurity concentration than the third semiconductor layer, and is shallower from the second main surface than the third semiconductor layer.

The semiconductor device according to the embodiment of the present invention has a two-stage buffer structure. Such a configuration reduces or eliminates an increase in the leakage current and prevents the voltage from oscillation during the turn-off. Such a configuration also enables an adequate supply of holes from the second main surface (back surface) of the semiconductor substrate, to thus improve a breakdown capacity.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a graph showing a result of a simulation of electric field distribution while an insulated gate bipolar transistor (IGBT) is short-circuited;

FIG. 2 is a sectional view of an IGBT according to a first preferred embodiment of the present invention;

FIG. 3 is a diagram of conductive paths of holes while the IGBT according to the first preferred embodiment is turned on;

FIGS. 4 to 12 are diagrams illustrating process steps of a method for manufacturing the IGBT according to the first preferred embodiment;

FIG. 13 is a graph of an exemplary impurity-concentration profile on a back surface of the IGBT according to the first preferred embodiment; and

FIG. 14 is a graph showing a result of a simulation of a relationship between the size of regions absent from a shallow n⁺ buffer layer and leakage current in the IGBT according to the first preferred embodiment.

### DESCRIPTION OF THE PREFERRED EMBODIMENTS

### First Preferred Embodiment

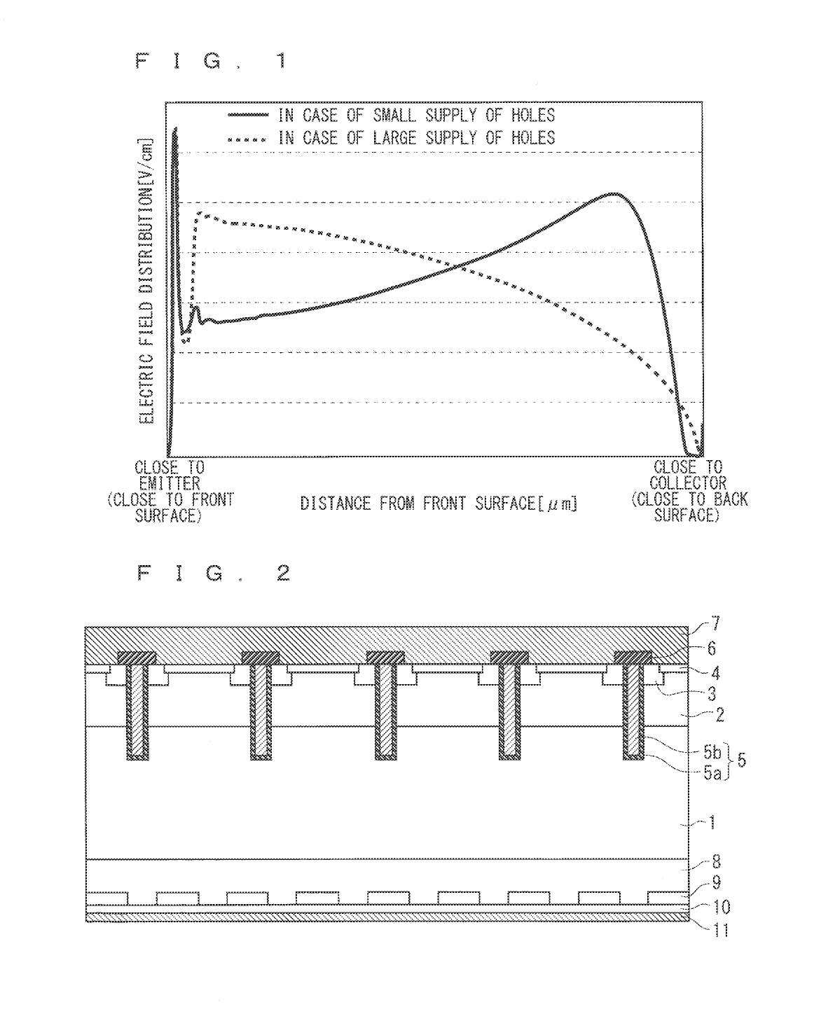

The inventors have run a simulation of electric field distribution while an insulated gate bipolar transistor (IGBT) is short-circuited. FIG. 1 is a graph showing a result of the simulation, and FIG. 1 shows the electric field distribution within the IGBT when voltages of Vce=800 V and Vge=15 V are applied to a shorted circuit of the IGBT whose breakdown voltage is in the range of 1200 V. FIG. 1 reveals that an electric field is higher near a back surface (surface close to a collector) of the IGBT than near a front surface (surface close to an emitter) of the IGBT because a depletion layer extends from near the back surface in a small supply of holes. Such an electric field distribution readily causes the IGBT device to breakdown. On the other hand, FIG. 1 has clarified that an electric field peak appears near the front surface in a large supply of holes, to improve a short-circuit capacity. The inventors have studied a structure of a buffer layer that is capable of reducing or eliminating an increase in leakage current, and that is capable of preventing voltage from oscillation while the IGBT is turned off with an adequate supply of holes being maintained. This study has led the inventors to the present invention.

FIG. 2 is a sectional view of the IGBT, which is a semiconductor device, according to the first preferred embodiment of the present invention. As illustrated in FIG. 2, the IGBT is made using a semiconductor substrate 1 The semiconductor substrate 1 is a silicon wafer in which an n-type semiconductor layer (first semiconductor layer) is disposed (hereinafter, the semiconductor substrate 1 is referred to as an “n-type silicon substrate”). The n-type silicon substrate 1 includes a p-type base layer 2 (second semiconductor layer, hereinafter referred to as a “p base layer”) disposed on a surface layer of a front surface (first main surface) of the n-type silicon substrate 1. The p base layer 2 has a higher impurity concentration than the n-type silicon substrate 1. The p base layer 2 includes an n⁺-type emitter layer 3 (hereinafter referred to as an “n⁺ emitter layer”) and a p⁺-type contact layer 4 (hereinafter referred to as a “p⁺ contact layer”) each disposed on a surface layer of the p base layer 2.

The n-type silicon substrate 1 is provided with trenches to pass through the n⁺ emitter layer 3 and the p base layer 2. The trench is provided with embedded trench gate 5. The trench gate 5 includes a gate insulating film 5a and a gate electrode 5b. The gate insulating film 5a is disposed on side and bottom surfaces of the gate electrode 5b. The trench gate 5 has a side surface in contact with the n⁺ emitter layer 3 and the p base layer 2 under the n⁺ emitter layer 3. The trench gate 5 has a bottom surface that reaches an n-type region under the p base layer 2. As such, the gate insulating film 5a is interposed between the gate electrode 5b and the n-type silicon substrate 1, between the gate electrode 5b and the p base layer 2, and between the gate electrode 5b and the n⁺ emitter layer 3.

An interlayer dielectric 6 is disposed on a top surface of the n-type silicon substrate 1, to cover the trench gate 5. Contact holes that reach the n⁺ emitter layer 3 and the p⁺ contact layer 4 are formed in the interlayer dielectric 6. An emitter electrode 7 is disposed on the interlayer dielectric 6. The emitter electrode 7 is coupled to the n⁺ emitter layer 3 and the p⁺ contact layer 4 through the contact holes. Further, the n-type silicon substrate 1 includes an n⁺-type buffer layer 8 (third semiconductor layer) disposed on a surface layer of a back surface (second main surface) of the n-type silicon substrate 1. The n⁺-type buffer layer 8 is disposed at a relatively great depth from the back surface of the wafer (hereinafter referred to as a “deep n⁺ buffer layer”). Further, the deep n⁺ buffer layer 8 includes an n⁺-type buffer layer 9 (fourth semiconductor layer) disposed on a surface layer of a back surface of the deep n⁺ buffer layer 8. The n⁺-type buffer layer 9 is disposed at a relatively shallow depth from the back surface of the wafer (hereinafter referred to as a “shallow n⁺ buffer layer”). The deep n⁺ buffer layer 8 and the shallow n⁺ buffer layer 9 have higher impurity concentrations than the n-type silicon substrate 1.

The shallow n⁺ buffer layer 9 has a higher impurity concentration than the deep n⁺ buffer layer 8; that is, the shallow n⁺ buffer layer 9 is set to have a higher peak impurity concentration than the deep n⁺ buffer layer 8. Further, the deep n⁺ buffer layer 8 is disposed throughout a region close to the back surface of the n-type silicon substrate 1, whereas the shallow n⁺ buffer layer 9 does not. The shallow n⁺ buffer layer 9 is selectively disposed close to the back surface of the n-type silicon substrate 1; that is, the deep n⁺ buffer layer 8 is provided with regions that are absent from the shallow n⁺ buffer layer 9 (regions absent from the shallow n⁺ buffer layer 9) on the surface layer of the back surface of the deep n⁺ buffer layer 8.

Although for the deep n⁺ buffer layer 8, phosphorus or a proton can be used as an impurity (dopant), protons are used in the first preferred embodiment. For the shallow n⁺ buffer layer 9, phosphorus or arsenic can be used as an impurity.

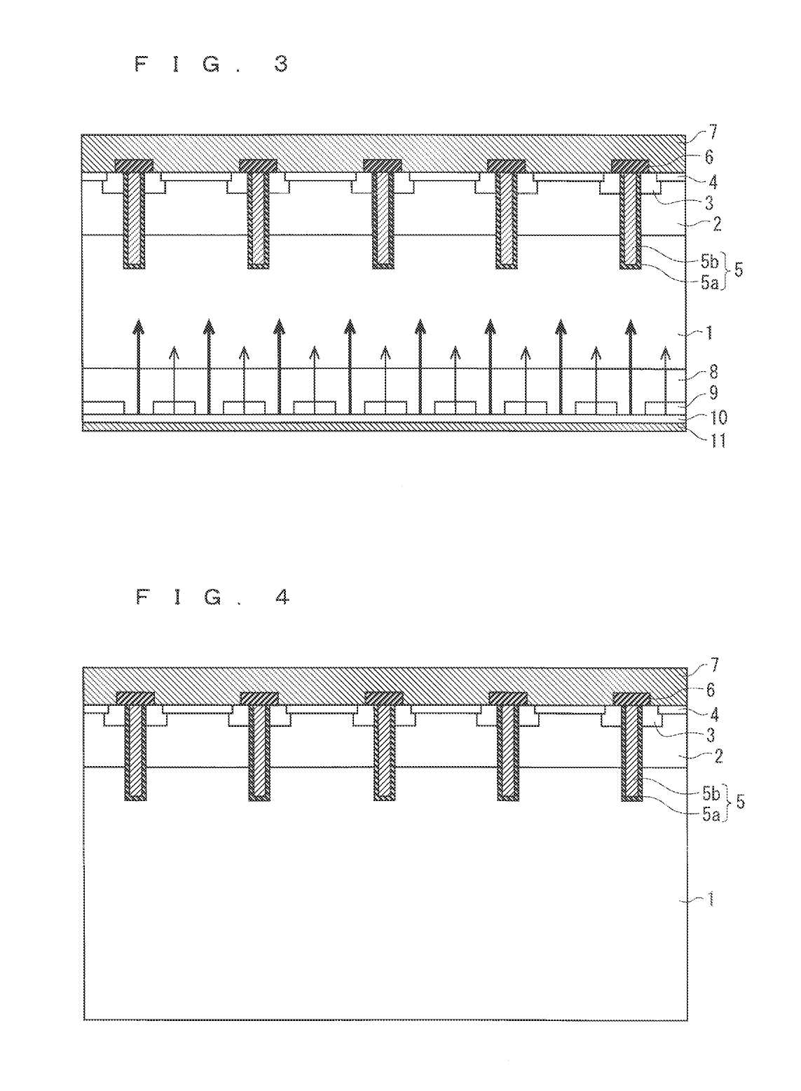

Further, the wafer includes a p collector layer 10 on an outermost surface layer of the back surface of the wafer. A collector electrode 11 is disposed on the back surface of the wafer so as to be in contact with the p collector layer 10. FIG. 3 is a diagram illustrating conductive paths of holes while the IGBT in

FIG. 2 is turned on. In FIG. 3, any arrows denote the conductive paths of the holes from the back surface of the IGBT. The region, in which the shallow n⁺ buffer layer 9 is present, has a low concentration of hole because the holes are rejoined to disappear in this region. In contrast, the regions, which are absent from the shallow n⁺ buffer layer 9, have a high concentration of hole. This enables the IGBT to have a high concentration of hole on the back surface of the IGBT if the IGBT is short-circuited, and also reduces an increase in electric field close to the back surface of the IGBT. In other words, the electric field distribution within the IGBT has its peak in a position close to the front surface, as indicated by a dashed-line graph in FIG. 1, to thus enhance a short-circuit capacity.

Further, the deep n⁺ buffer layer 8 and the shallow n⁺ buffer layer 9 constitute a two-stage buffer structure. This two-stage buffer structure reduces the leakage current in the IGBT, and prevents voltage from oscillation while the IGBT is turned off. Hence, the first preferred embodiment provides an IGBT that has less leakage current, prevents the voltage from oscillation, and has a high short-circuit capacity.

In particular, setting the deep n⁺ buffer layer 8 to have a depth of equal to or more than 10 μm prevents exhaustion in carrier on the back surface during the turn-off, and also prevents the voltage from oscillation effectively. Further, providing the shallow n⁺ buffer layer 9 to have a depth of equal to or less than 3 μm effectively stops the depletion layer from extending when a voltage is applied to the collector electrode 11. This prevents an increase in the leakage current.

The following describes a method for manufacturing the IGBT illustrated in FIG. 2. FIGS. 4 to 12 illustrate process steps of the method.

A structure close to the front surface (first main surface) of the IGBT in FIG. 2 is similar to that of a conventional IGBT and is made similarly to the conventional IGBT. Thus, provided here is a brief description. First of all, the n-type silicon substrate 1 is prepared, and various impurities are selectively implanted, through ion implantation, into a surface layer of the front surface of the n-type silicon substrate 1, to thus make the p base layer 2, the n⁺ emitter layer 3, and the p⁺ contact layer 4. Subsequently, the front surface of the n-type silicon substrate 1 selectively undergoes etching, to thus make the trenches, which pass though the n⁺ emitter layer 3 and the p base layer 2. Then, an insulating film and an electrode material are formed on the front surface of the n-type silicon substrate 1, including the insides of the trenches. Then, the insulating film and the electrode material undergo a patterning process or an etchback process, to thus make the trench gate 5, which includes the gate insulating film 5a and the gate electrode 5b, within the trenches. Furthermore, the interlayer dielectric 6 is formed on the whole front surface of the n-type silicon substrate 1, and the contact holes are formed in the interlayer dielectric 6 to reach a top surface of the n⁺ emitter layer 3 and a top surface of the contact layer 4, and then the emitter electrode 7 is formed on the interlayer dielectric 6. A structure illustrated in FIG. 4 is completed through these steps. At this stage, the wafer is almost as thick as a bare wafer (about 700 μm in thickness).

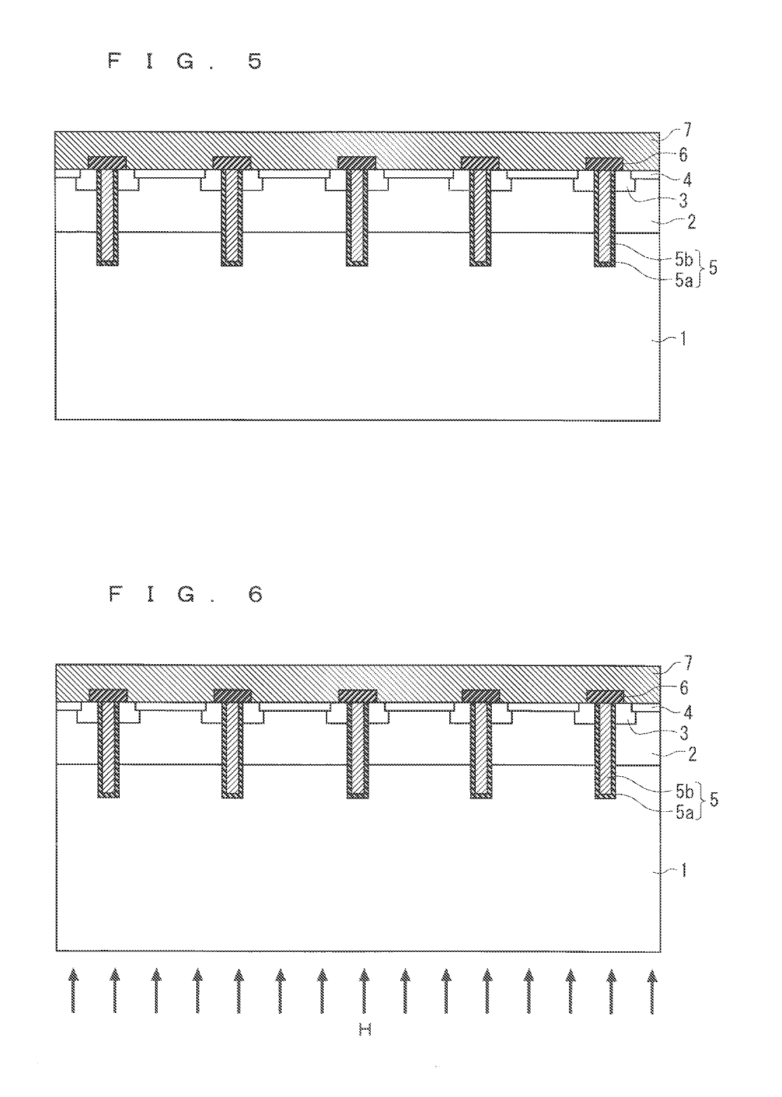

Subsequently provided is a structure close to the back surface (second main surface) of the IGBT. First of all, the back surface of the n-type silicon substrate 1 undergoes a polishing process using a grinder or a wet-etching process to thus cause the wafer to be as thin as is desired, as illustrated in FIG. 5.

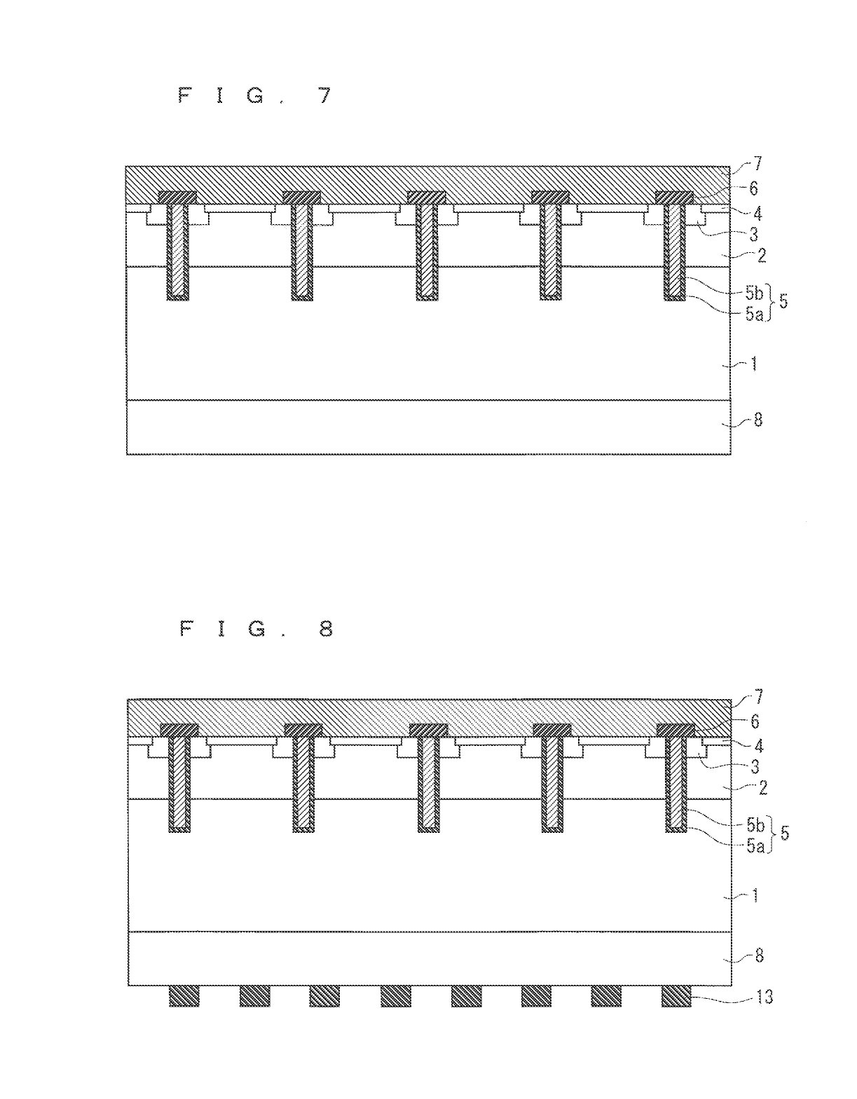

Next, a bottom surface of the n-type silicon substrate 1 undergoes a plurality of proton-ion-implantation processes at an acceleration voltage of 500 keV to 1500 keV, as illustrated in FIG. 6. Through these processes, the deep n⁺ buffer layer 8 is formed on the surface layer of the bottom surface of the n-type silicon substrate 1, as illustrated in FIG. 7. Protons have a range of about 6 μm at an acceleration voltage of 500 keV, and a range of about 30 μm at an acceleration voltage of 1500 keV. Thus, using a typical ion implantation apparatus for manufacturing semiconductors without using an accelerator, such as a cyclotron or Van de Graaff accelerator provides the deep n⁺ buffer layer 8 with a depth of equal to or more than 10 μm, where the depth is effective to prevent the voltage from oscillation during the turn-off.

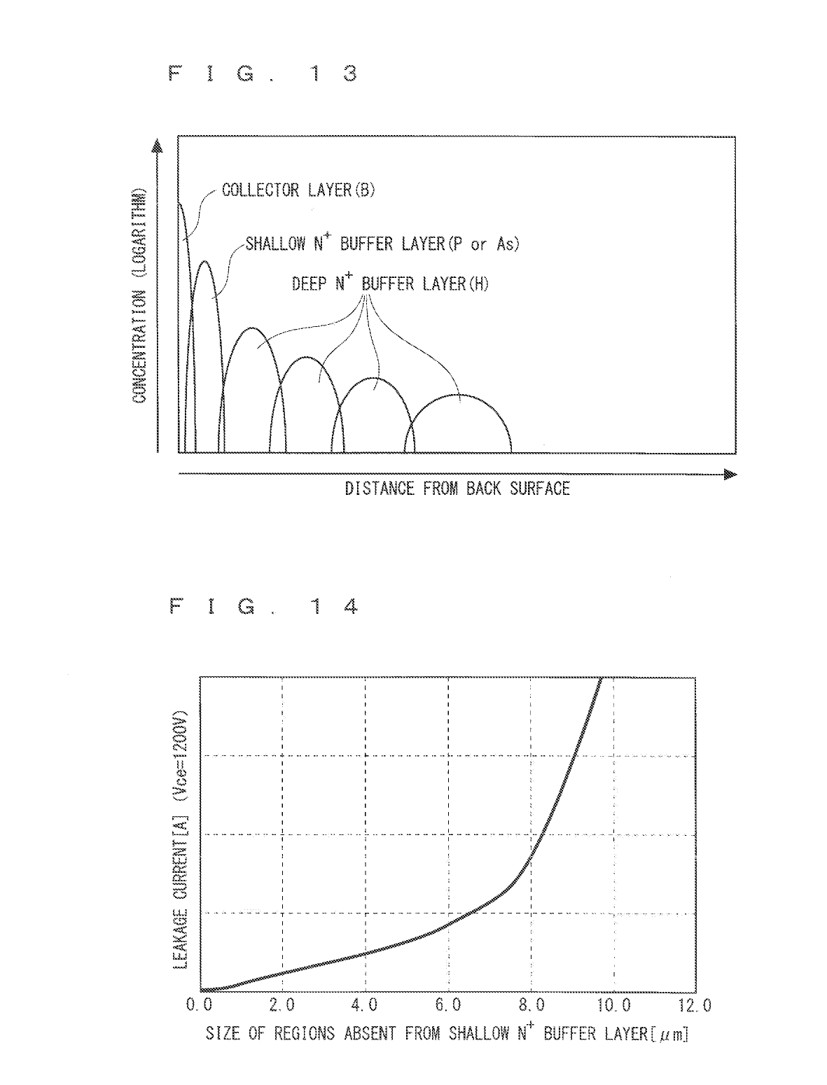

Further, the deep n⁺ buffer layer 8 is formed through a plurality of ion implantation processes each employing a different acceleration voltage, to thus make the deep n⁺ buffer layer 8 with a broad impurity profile as if produced through thermal diffusion. FIG. 13 is a graph of an exemplary impurity-concentration-profile in a depth direction of the back surface of the IGBT in preforming a plurality of ion implantation processes (four times of ion implantation). The graph reveals that several concentration peaks of the deep n⁺ buffer layer 8 appear as a result of the plurality of ion implantation processes each employing a different acceleration voltage. After the deep n⁺ buffer layer 8 is formed, the back surface of the IGBT undergoes furnace annealing at about 350 to 450° C., to thus activate the protons, which have been implanted into the deep n⁺ buffer layer 8.

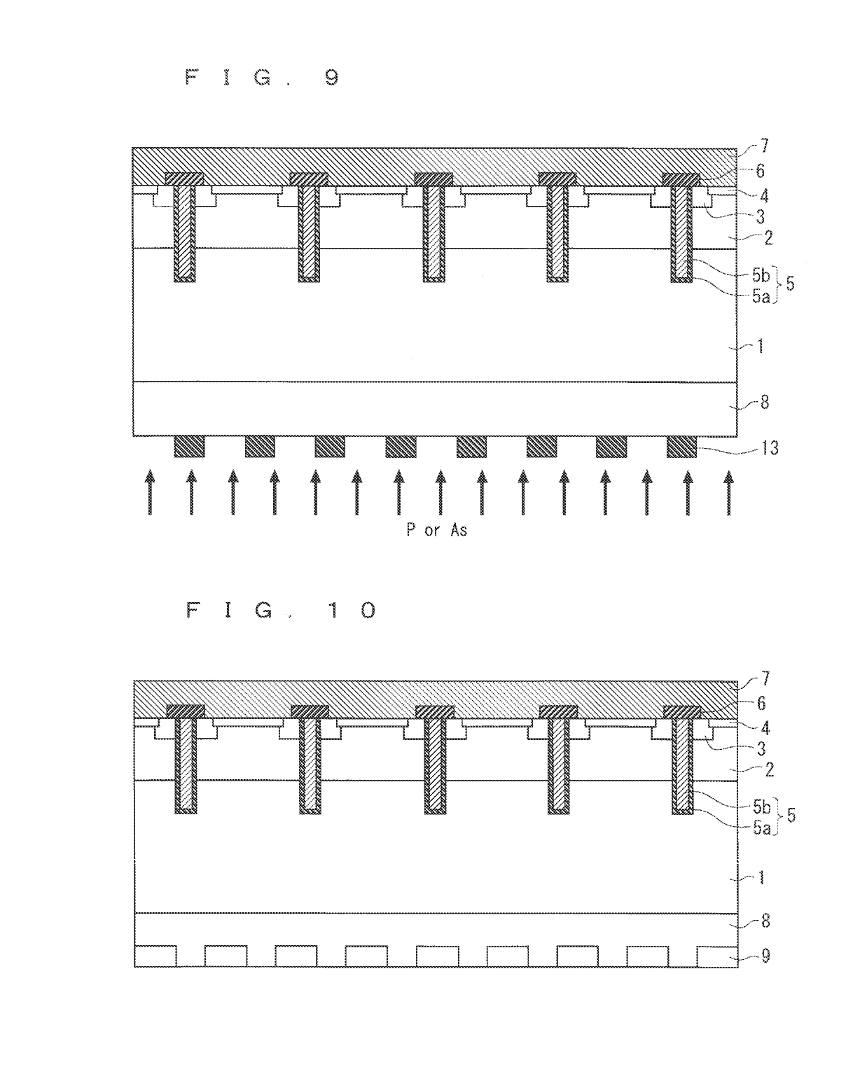

Next, a resist 13 is formed using a photolithography technique, as illustrated in FIG. 8 with the region in which the shallow n⁺ buffer layer 9 is present is opened (conversely, the resist 13 serves as a pattern that covers the regions absent from the shallow n⁺ buffer layer 9). Subsequently, as illustrated in FIG. 9, phosphorus or arsenic is implanted into a shallow region having a depth of equal to or less than 3 μm from the back surface of the wafer, and then the resist 13 is removed. As a result, the shallow n⁺ buffer layer 9 is selectively formed on the surface layer of the deep n⁺ buffer layer 8, as illustrated in FIG. 10. Subsequently, the back surface of the IGBT undergoes a heating process through laser annealing to activate phosphorus or arsenic that has been implanted into the shallow n⁺ buffer layer 9.

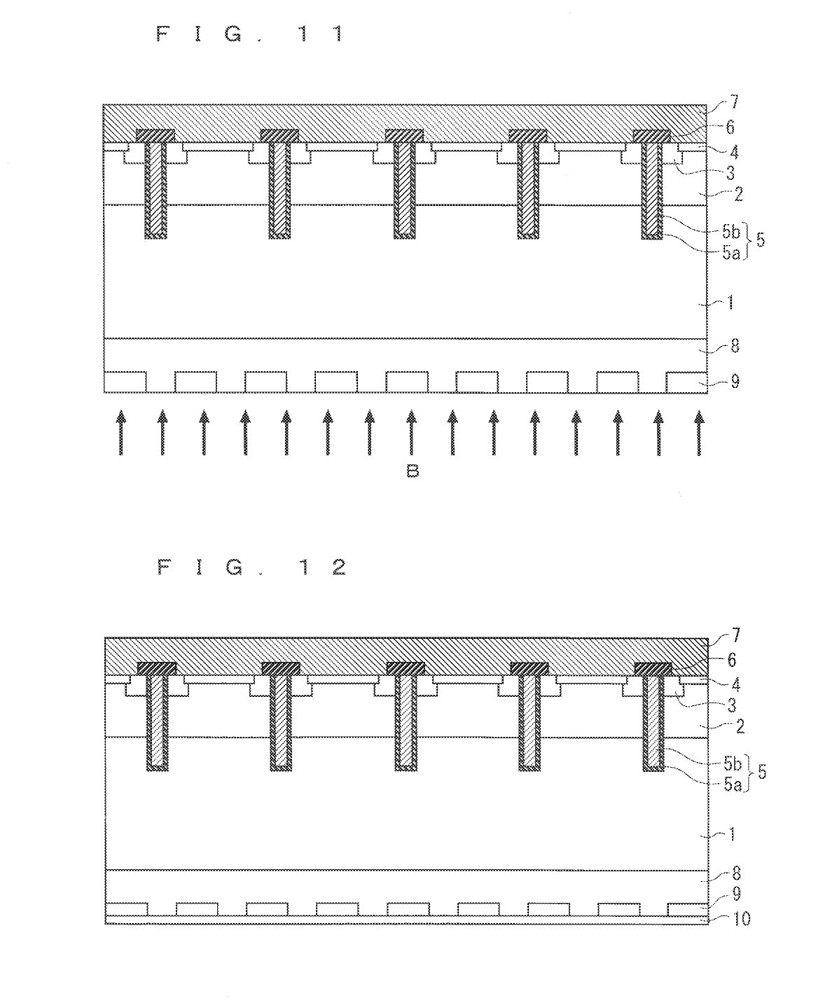

Then, as illustrated in FIG. 11, boron is implanted into the back surface of the wafer. As a result, the p collector layer 10 is formed in surface layers of the deep n⁺ buffer layer 8 and shallow n⁺ buffer layer 9, as illustrated in FIG. 12. Then, the back surface of the IGBT undergoes a heating process through laser annealing to activate boron that has been implanted into the p collector layer 10.

Subsequently, a film, such as a stacked film of Al/Ti/Ni/Au or a stacked film of AlSi/Ti/Ni/Au is formed on the back surface of the wafer through spattering, to thus make the collector electrode 11. Then, the back surface of the IGBT undergoes a heating process to bring the collector electrode 11 and silicon (the deep n⁺ buffer layer 8 and the shallow n⁺ buffer layer 9) into ohmic contact with each other. This reduces a contact resistance between the collector electrode 11 and the silicon. These steps complete the IGBT with the structure as illustrated in FIG. 2.

### Second Preferred Embodiment

The first preferred embodiment uses the protons as the impurity (dopant) for the deep n⁻ buffer layer 8. However, as earlier mentioned, phosphorus may be used. Phosphorus, when used, is implanted into the back surface of the wafer through ion implantation, followed by diffusing phosphorus through a heating process at a high temperature of equal to or higher than 1100° C., to thus make the deep n⁺ buffer layer 8. In this case, individual steps are desirably sequenced so that a metal-oxide-semiconductor (MOS) structure and an electrode that are positioned close to the front surface of the IGBT are not under the influence of the above-mentioned heating process. In other words, prior to forming the MOS structure close to the front surface of the IGBT, the back surface of the wafer preferably undergoes a polishing process or a wet-etching process to make the wafer thin, followed by forming the deep n⁺ buffer layer 8. For instance, the sequence of the steps desirably starts with forming the deep n⁺ buffer layer 8 close to the back surface, followed by forming the MOS structure close to the front surface, followed by forming the shallow n⁺ buffer layer 9 close to the back surface.

### Third Preferred Embodiment

In the shallow n⁺ buffer layer 9 being selectively formed as described in the first preferred embodiment, the holes are supplied from the regions absent from the shallow n⁺ buffer layer 9 when the breakdown voltage is maintained. Hence, if the regions absent from the shallow n⁺ buffer layer 9 are excessively large, the leakage current can increase. Accordingly, the inventors have studied an optimal size of the regions absent from the shallow n⁺ buffer layer 9.

FIG. 14 is a graph showing a result of a simulation of a relationship between the size of the regions absent from the shallow n⁺ buffer layer 9 and the leakage current in the IGBT according to the first preferred embodiment (FIG. 2). Provided here is a simulation on how the leakage current varies depending on changes in size (diameter) of the regions absent from the shallow n⁺ buffer layer 9, when a voltage, Vce=1200 V, is applied to the IGBT, which has the breakdown voltage is in the range of 1200 V. The simulation reveals that the leakage current suddenly increases when the size the regions absent from the shallow n⁺ buffer layer 9 exceeds 6 μm, as shown in FIG. 14. Accordingly, the shallow n⁺ buffer layer 9 is preferably set to have a size of equal to or less than 6 μm.

Reference is made to the size of a unit cell that includes the region in which the shallow n⁺ buffer layer 9 are present and the regions absent from the shallow n⁺ buffer layer 9. A small unit cell with the regions absent from the shallow n⁺ buffer layer 9 having a fixed size effectively produces more regions absent from the shallow n⁺ buffer layer 9 in a surface of a chip. Hence, the leakage current tends to increase, whereas the short-circuit capacity tends to be improved. An allowable value of the leakage current is determined in a value that does not cause thermal runaway when voltage is applied to a device within a guaranteed temperature. Thus, the size of the unit cell, which includes the region in which the shallow n⁺ buffer layer 9 is present and the regions absent from the shallow n⁺ buffer layer 9, is desirably determined in view of the leakage current.

### Fourth Preferred Embodiment

The first preferred embodiment describes performing the heating process through furnace annealing to activate the deep n⁻ buffer layer 8 and performing the heating process through leaser annealing to activate the shallow n⁺ buffer layer 9. Furnace annealing provides about 1% of activation of the protons in the deep n⁺ buffer layer 8, whereas laser annealing provides about 70% of activation of phosphorus or arsenic in the shallow n⁺ buffer layer 9. Thus, even if the amount of to-be-implanted dopants (phosphorus or arsenic) for the shallow n⁺ buffer layer 9 is less than the amount of to-be-implanted protons for the deep n⁺ buffer layer 8, the shallow n⁺ buffer layer 9 has a peak in impurity concentration sufficiently higher than a peak in impurity concentration of the deep n⁺ buffer layer 8.

Reducing the amount of to-be-implanted dopants for the shallow n⁺ buffer layer 9 minimizes damage close to the back surface of the wafer, caused by the ion implantation. In particular, when the dopant for the deep n⁺ buffer layer 8 is the protons, an activation rate of the protons affects the amount of defects in liquid crystals. Hence, minimizing the damage close to the back surface minimizes variations in the activation rate of the protons and also contributes to an improved reliability of a device.

### Fifth Preferred Embodiment

The first preferred embodiment describes that the heating process for activating the deep n⁺ buffer layer 8, which has been formed using the protons, and the heating process for reducing the contact resistance of the collector resistance 11 are separated. However, both heating processes, which are performed at the temperature of 350 to 450° C., may be performed in the same step. In other words, the heating process for the deep n⁺ buffer layer 8 and the heating process for the collector electrode 11 may be performed at the same time after the collector electrode 11 being formed. A reduction in number of heating processes provides lower manufacturing costs.

Although the preferred embodiments use the semiconductor substrate 1 as a silicon substrate, the semiconductor substrate 1 may be made of silicon carbide (SiC). A silicon carbide substrate, when used to make the semiconductor device according to the present invention, provides a semiconductor device that well operates under a high voltage, large current and high temperature, when compared with a semiconductor device that uses a silicon substrate.

It is to be noted that in the present invention, respective preferred embodiments can be freely combined, or can be modified and omitted as appropriate, within the scope of the invention.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a semiconductor substrate comprising a first main surface and a second main surface;
a first semiconductor layer having n-type conductivity and disposed in said semiconductor substrate;
a second semiconductor layer having p-type conductivity and disposed close to said first main surface in said first semiconductor layer, said second semiconductor layer having a higher impurity concentration than said first semiconductor layer; and
a third semiconductor layer and a fourth semiconductor layer each having n-type conductivity and disposed close to said second main surface in said first semiconductor layer, said third semiconductor layer and said fourth semiconductor layer having higher impurity concentrations than said first semiconductor layer,
wherein said third semiconductor layer is disposed throughout a region close to said second main surface in said first semiconductor layer,
wherein said fourth semiconductor layer is selectively disposed close to said second main surface in said first semiconductor layer, and
wherein said fourth semiconductor layer has a higher impurity concentration than said third semiconductor layer, and is shallower from said second main surface than said third semiconductor layer.

2. The semiconductor device according to claim 1, wherein regions absent from said fourth semiconductor layer each have a size of equal to or less than 6 μm.

3. The semiconductor device according to claim 1, wherein said third semiconductor layer has a depth of equal to or more than 10 μm from said second main surface.

4. The semiconductor device according to claim 1, wherein said fourth semiconductor layer has a depth of equal to or less than 3 μm from said second main surface.

5. The semiconductor device according to claim 1,
wherein said third semiconductor layer contains a proton or phosphorus as a dopant, and
wherein said fourth semiconductor layer contains phosphorus or arsenic as a dopant.

6. The semiconductor layer according to claim 1, wherein an impurity concentration profile in a depth direction of said third semiconductor layer includes a plurality of concentration peaks.

7. The semiconductor device according to claim 1,
wherein said semiconductor device comprises an insulated gate bipolar transistor (IGBT), and
wherein said second semiconductor layer comprises a base layer of said IGBT.

8. A method for manufacturing a semiconductor substrate, the method comprising:
preparing a semiconductor substrate comprising a first main surface and a second main surface, said semiconductor substrate being provided with a first semiconductor layer having n-type conductivity;
forming a second semiconductor layer having p-type conductivity in a position close to said first main surface in said first semiconductor layer, said second semiconductor layer having a higher impurity concentration than said first semiconductor layer; and
forming a third semiconductor layer and a fourth semiconductor layer each having n-type conductivity in a position close to said second main surface in said first semiconductor layer, said third semiconductor layer and said fourth semiconductor layer having higher impurity concentrations than said first semiconductor layer,
wherein said third semiconductor layer is disposed throughout a region close to said second main surface in said first semiconductor layer,
wherein said fourth semiconductor layer is selectively disposed close to said second main surface in said first semiconductor layer, and
wherein said fourth semiconductor layer is formed to have a higher impurity concentration than said third semiconductor layer, and to be shallower from said second main surface than said third semiconductor layer.

9. The method according to claim 8, wherein regions absent from said fourth semiconductor layer each have a size of equal to or less than 6 μm.

10. The method according to claim 8, wherein said third semiconductor layer has a depth of equal to or more than 10 μm from said second main surface.

11. The method according to claim 8, wherein said fourth semiconductor layer has a depth of equal to or less than 3 μm from said second main surface.

12. The method according to claim 8,
wherein said third semiconductor layer contains a proton or phosphorus as a dopant, and
wherein said fourth semiconductor layer contains phosphorus or arsenic as a dopant.

13. The method according to claim 8, wherein forming said third semiconductor layer is performed through a plurality of ion implantation processes each employing a different acceleration voltage.

14. The method according to claim 8, further comprising performing a heating process through laser annealing to activate said fourth semiconductor.

15. The method according to claim 8, further comprising performing a heating process through furnace annealing at equal to or higher than 350° C. and equal to or lower than 450° C. to activate said third semiconductor layer.

16. The method according to claim 8, further comprising forming an electrode onto said second main surface,
wherein said heating process for activating said third semiconductor layer is performed at a same time as a heating process for bringing said electrode into ohmic contact with said second main surface.

17. The method according to claim 8,
wherein said semiconductor device comprises an insulated gate bipolar transistor (IGBT), and
wherein said second semiconductor layer comprises a base layer of said IGBT.
